(19) United States
(12) Patent Application Publication
(10) Pub. No.: US 2026/0353711 A1
(43) Pub. Date: Nov. 5, 2026

(54) SEMICONDUCTOR DEVICE AND METHOD

(71) Applicant: Taiwan Semiconductor Manufacturing Co., Ltd., Hsinchu (TW)

(72) Inventors: Hua-Yuan Huang, New Taipei City (TW); Tsu-Hui Su, Taipei City (TW); Yu-Cheng Shiau, Hsinchu (TW); Keng Fang Hsu, Hsinchu (TW)

(21) Appl. No.: 19/734,509

(22) Filed: Jul. 8, 2026

Related U.S. Application Data
(63) Continuation of application No. 18/788,904, filed on Jul. 30, 2024.

(51) Int. Cl. H10D 30/67; H10D 30/01; H10D 30/43; H10D 62/10; H10D 62/13; H10D 64/01

(52) U.S. Cl. CPC H10D 30/6735; H10D 30/014; H10D 30/43; H10D 30/6757; H10D 62/121; H10D 62/151; H10D 64/017; H10D 30/6736

(57) ABSTRACT

A semiconductor device and the method of forming the same are provided. The semiconductor device may include a first nanostructure and a second nanostructure, a gate structure between the first nanostructure and the second nanostructure, a source/drain region along sidewalls of the first nanostructure and the second nanostructure, and a spacer layer between the source/drain region and gate structure. A first portion of the spacer layer may protrude from the source/drain region towards the gate structure. The first portion of the spacer layer may protrude into a recess of the gate structure.

### CROSS-REFERENCE TO RELATED APPLICATIONS

This application is a continuation of U.S. Patent Application No. 18/788,904, filed on Jul. 30, 2024, and entitled “Semiconductor Device and Method,” which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 12A, 12B, 12C, 12D, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, and 20C are views of intermediate processes in the manufacturing of a semiconductor device (e.g., a nano-FET), in accordance with some embodiments.

FIGS. 21A, 21B, 21C, 22A, 22B, 22C, 23A, 23B, 23C, 24A, 24B, and 24C are views of intermediate processes in the manufacturing of a semiconductor device (e.g., a nano-FET), in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices and methods of forming the same. The semiconductor devices may be nano-FETs including channel regions, source/drain regions on sidewalls of the channel regions, gate structures between adjacent channel regions, and inner spacers on sidewalls of the gate structures. Some embodiments provide methods of forming the nano-FETs including inner spacers and gate structures of certain shapes and sizes by forming first sacrificial layers and second sacrificial layers of certain shapes and sizes between the adjacent channel regions. The inner spacers with such shapes and sizes may provide sufficient electrical insulation between the source/drain regions and the gate structure, thereby reducing or eliminating current leakage between the gate structures and the source/drain regions. The gate structures with such shapes and sizes may lead to reduced resistance in the channel regions. As a result, the performance and reliability of the semiconductor devices may be improved.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

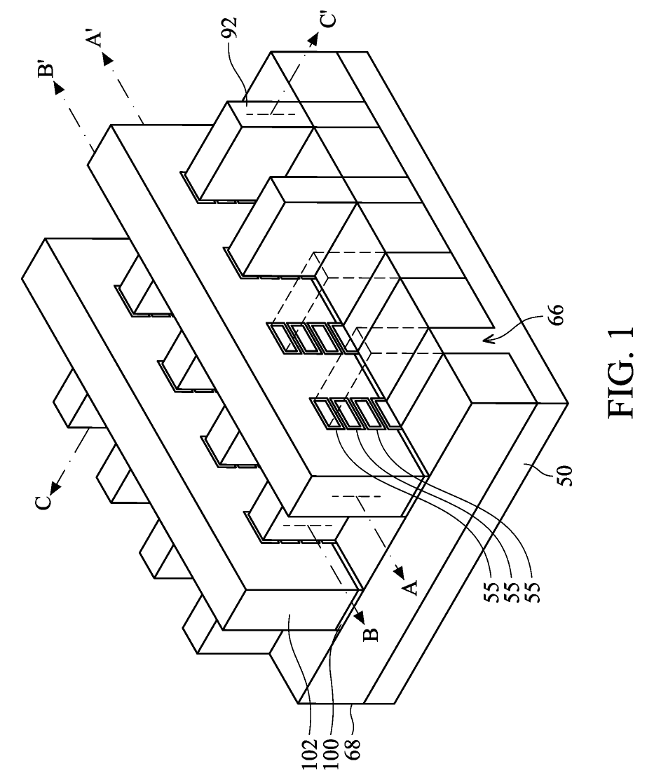

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A’ is along a longitudinal axis of a gate electrode 102 and in a direction, for example, perpendicular to the direction of current flow between the epitaxial source/drain regions 92 of a nano-FET. Reference cross-section B-B’ is parallel to the reference cross-section A-A’ and extends through epitaxial source/drain regions 92 of multiple nano-FETs. Reference cross-section C-C’ is perpendicular to the reference cross-section A-A’ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used.

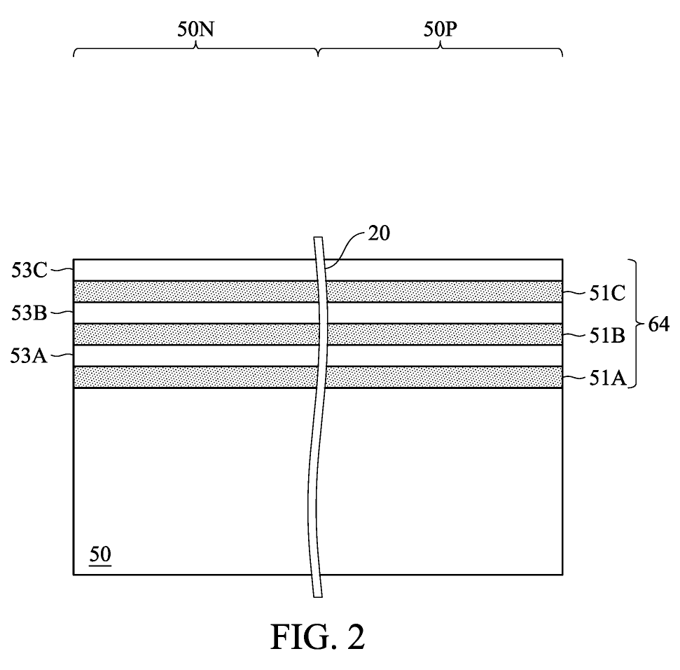

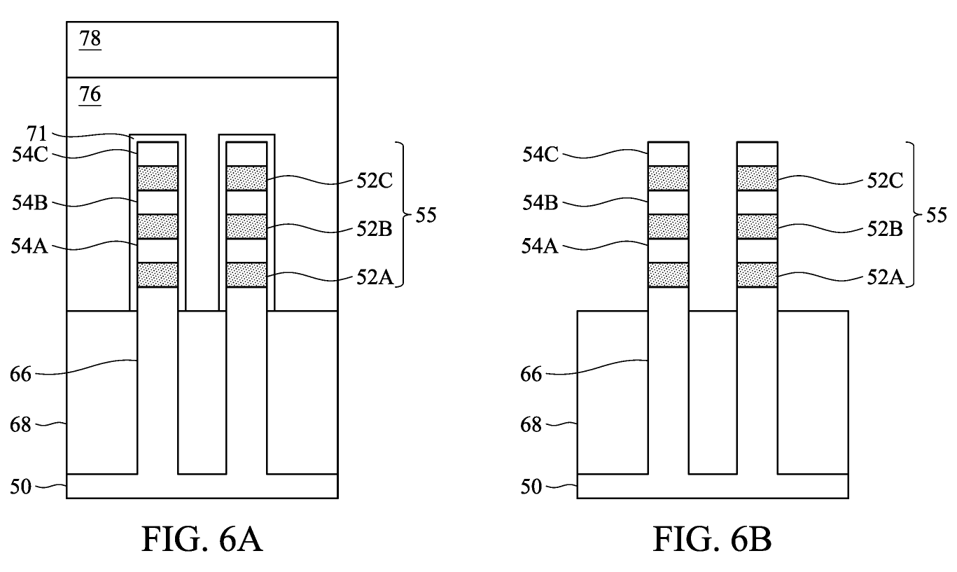

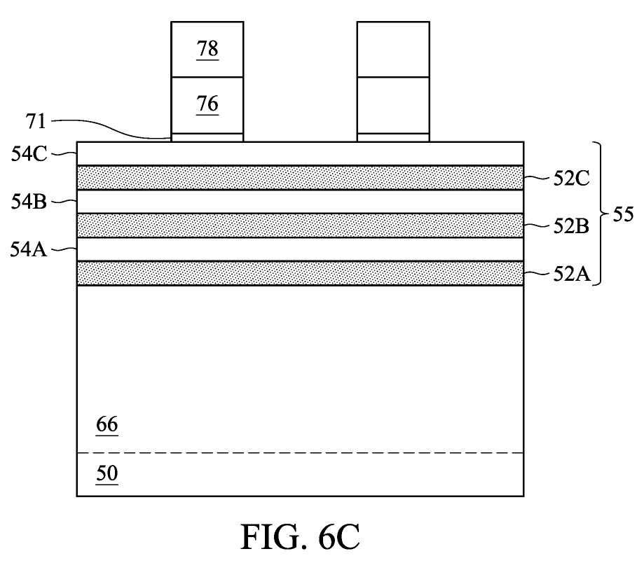

FIGS. 2 through 20C are views of intermediate processes in the manufacturing of a semiconductor device (e.g., a nano-FET), in accordance with some embodiments. FIGS. 2, 3, 4, 5, 6A, 7A, 8A, 9A, 10A, 11A, 12A, 13A, 14A, 15A, 16A, 17A, 18A, 19A, and 20B illustrate cross-sectional views along the reference cross-section A-A’ illustrated in FIG. 1. FIGS. 6B, 7B, 8B, 9B, 10B, 11B, 12B, 12D, 13B, 14B, 15B, 16B, 17B, 18B, 19B, and 20B illustrate cross-sectional views along the reference cross-section B-B’ illustrated in FIG. 1. FIGS. 6C, 7C, 8C, 9C, 10C, 11C, 12C, 13C, 14C, 15C, 16C, 17C, 18C, 19C, and 20C illustrate cross-sectional views along the reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 may be removed and the second semiconductor layers 53 may be patterned to form channel regions of nano-FETs in the n-type region 50N and the p-type region 50P. In some embodiments, the first semiconductor layers 51 are removed and the second semiconductor layers 53 are patterned to form channel regions of nano-FETs in the n-type region 50N, and the second semiconductor layers 53 are removed and the first semiconductor layers 51 are patterned to form channel regions of nano-FETs in the p-type region 50P. In some embodiments, the second semiconductor layers 53 are removed and the first semiconductor layers 51 are patterned to form channel regions of nano-FETs in the n-type region 50N, and the first semiconductor layers 51 are removed and the second semiconductor layers 53 are patterned to form channel regions of nano-FETs in the p-type region 50P. In some embodiments, the second semiconductor layers 53 are removed and the first semiconductor layers 51 are patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon or the like.

The first semiconductor materials and the second semiconductor materials may be materials having a high etching selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

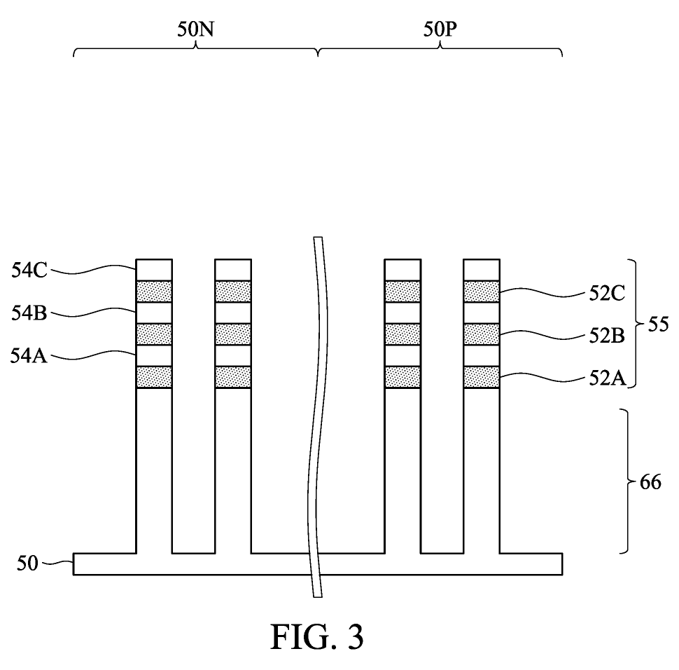

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

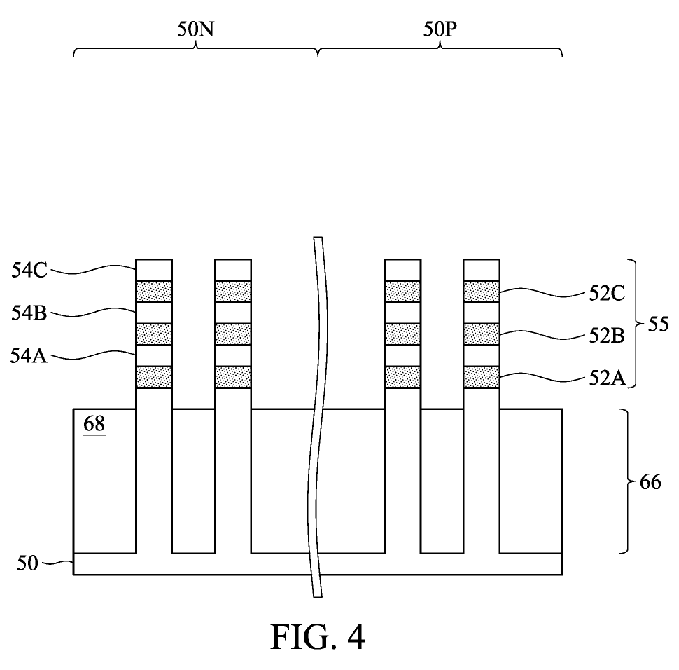

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, such as silicon nitride, the like, or a combination thereof, and may be formed by high-density plasma CVD (HDP-CVD), flowable CVD (FCVD), the like, or a combination thereof. Other insulation materials formed by any acceptable process may be used. An anneal process may be performed once the insulation material is formed. Although the insulation material is illustrated as a single layer, some embodiments may utilize multiple layers.

A removal process may be then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete. The insulation material may be then recessed to form the STI regions 68. The insulation material may be recessed such that upper portions of fins 66 in the n-type region 50N and the p-type region 50P protrude from between neighboring STI regions 68. The STI regions 68 may be recessed using an acceptable etching process, such as one that is selective to the material of the insulation material and etches the material of the insulation material at a faster rate than the material of the fins 66 and the nanostructures 55. For example, dilute hydrofluoric acid may be used when the insulation material is an oxide. After the removal process, the top surfaces of the STI regions 68 may have a flat surface as illustrated, a convex surface, a concave surface, or a combination thereof.

The process described above with respect to FIGS. 2 through 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) are illustrated and discussed herein as comprising the same materials in the p-type region 50P and the n-type region 50N, and the second semiconductor layers 53 (and resulting second nanostructures 54) are illustrated and discussed herein as comprising the same materials in the p-type region 50P and the n-type region 50N for illustrative purposes. In some embodiments, the first semiconductor layers 51 may comprise different materials in the p-type region 50P and the n-type region 50N. In some embodiments, the second semiconductor layers 53 may comprise different materials in the p-type region 50P and the n-type region 50N. In some embodiments, the first semiconductor layers 51 may comprise different materials in the p-type region 50P and the n-type region 50N, and the second semiconductor layers 53 may comprise different materials in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

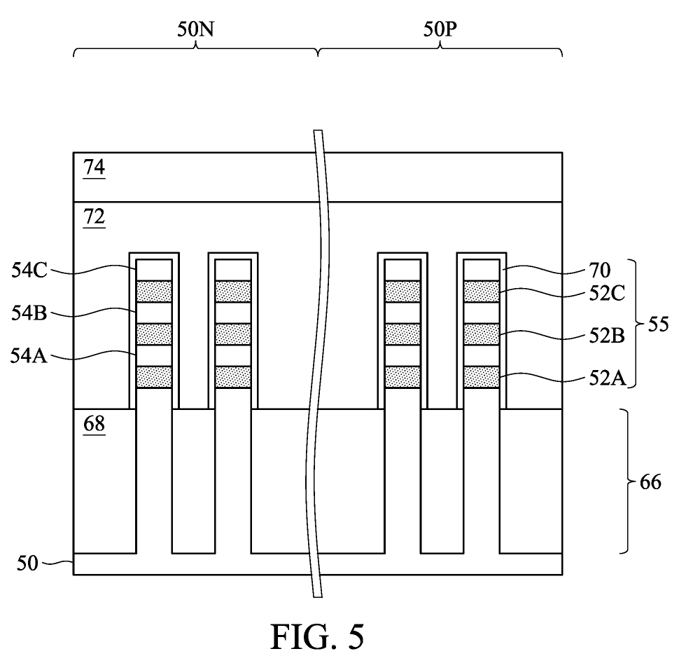

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity to the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 20C illustrate various additional processes in the manufacturing of the nano-FET device, in accordance to some embodiments. FIGS. 6A through 20C illustrate features in either or both the n-type region 50N or the p-type region 50P. In FIGS. 6A through 6C, masks 78, dummy gates 76, and dummy gate dielectrics 71 are formed. The dummy gates 76 and dummy gate dielectrics 71 may be collectively referred to as dummy gate structures. The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66 and the overlying respective nanostructures 55. The pattern of the masks 78 may be used to separate each of the dummy gates 76 from adjacent dummy gates 76. The dummy gates 76 may also have a lengthwise direction substantially perpendicular to the lengthwise direction of respective fins 66.

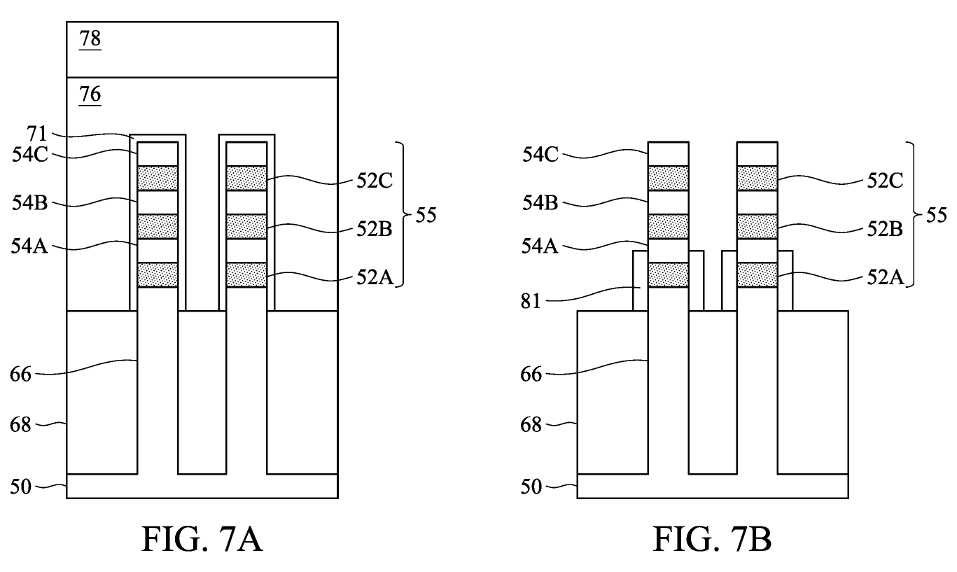

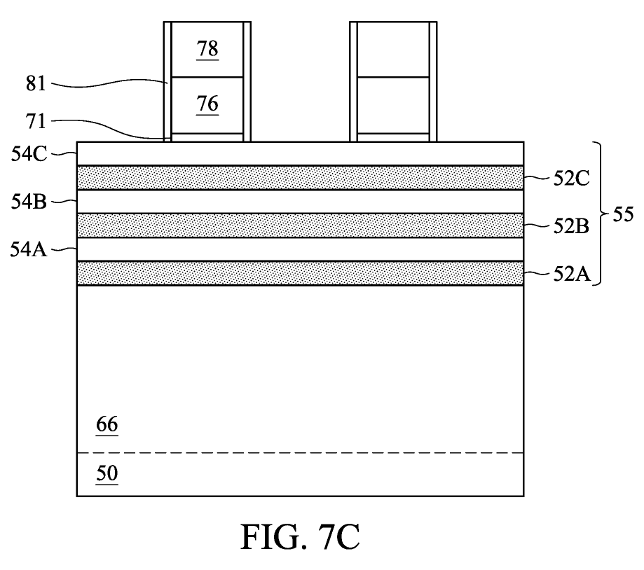

In FIGS. 7A through 7C, spacers 81 are formed. The spacers 81 may self-align subsequently formed source/drain regions, as well as protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon oxide, silicon nitride, silicon oxynitride, or the like. The spacers 81 may be formed by forming a spacer layer by thermal oxidation or a suitable deposition process, such as CVD, ALD, or the like, and then patterning the spacer layer by a suitable etching process, such as an isotropic etching process (e.g., a wet etching process), an anisotropic etching process (e.g., a dry etching process), or the like. The spacer layer may be formed on top surfaces of the STI regions 68; top surfaces and sidewalls of the fins 66, the nanostructures 55, and the masks 78; and sidewalls of the dummy gates 76 and the dummy gate dielectrics 71. After the etching process, the spacers 81 may remain on sidewalls of the fins 66 and/or nanostructures 55 as illustrated in FIG. 7B; and sidewalls of the masks 78, the dummy gates 76, and the dummy gate dielectrics 71 as illustrated in FIG. 7C.

In the embodiments in which the spacers 81 comprise two sublayers with different materials, after the first sublayer is formed and prior to forming the second sublayer, implants for lightly-doped source/drain (LDD) regions (not separately illustrated) may be performed. Similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1x10¹⁵ atoms/cm³ to about 1x10¹⁹ atoms/cm³. An annealing may be used to repair implant damage and to activate the implanted impurities.

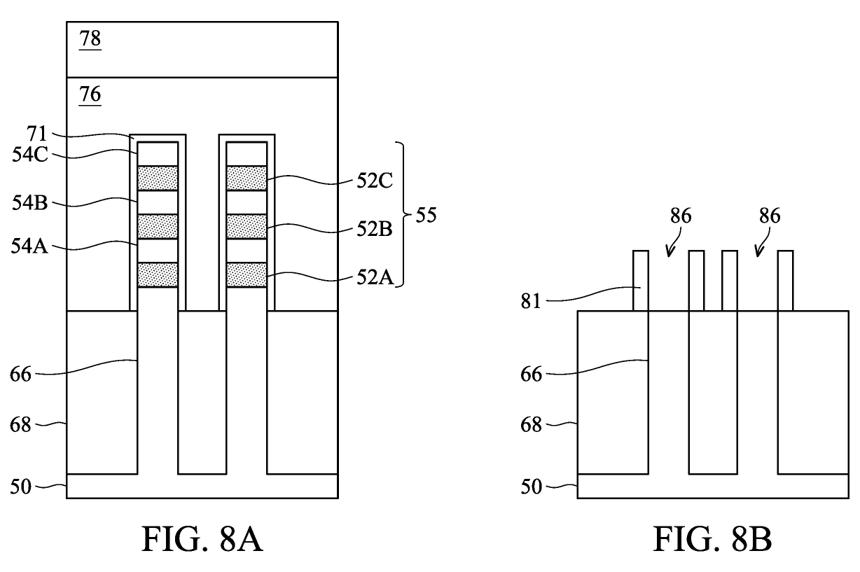

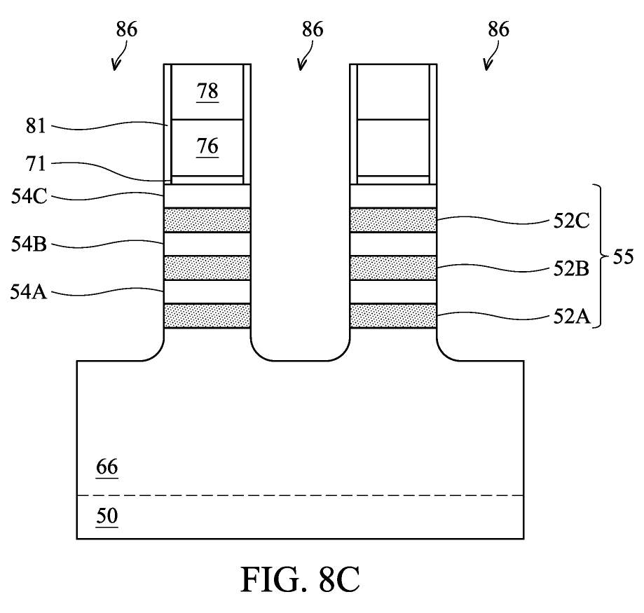

In FIGS. 8A through 8C, first recesses 86 are formed in the fins 66 and the nanostructures 55. The first recesses 86 may extend through the first nanostructures 52 and the second nanostructures 54, and into the fins 66. As illustrated in FIG. 8B, top surfaces of the STI regions 68 (e.g., top surfaces of the fins 66) may be level with bottom surfaces of the first recesses 86. In some embodiments, the bottom surfaces of the first recesses 86 are disposed below the top surfaces of the STI regions 68. The first recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching after the first recesses 86 reach desired depths.

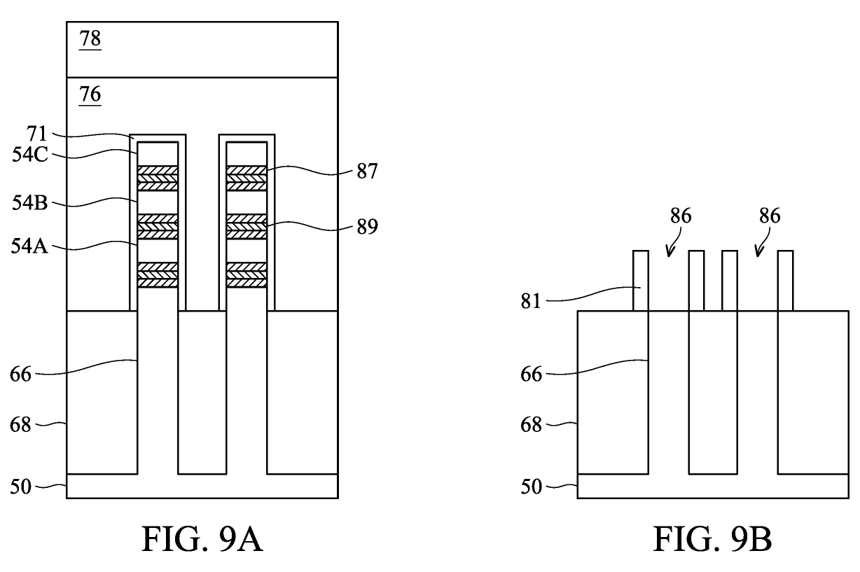

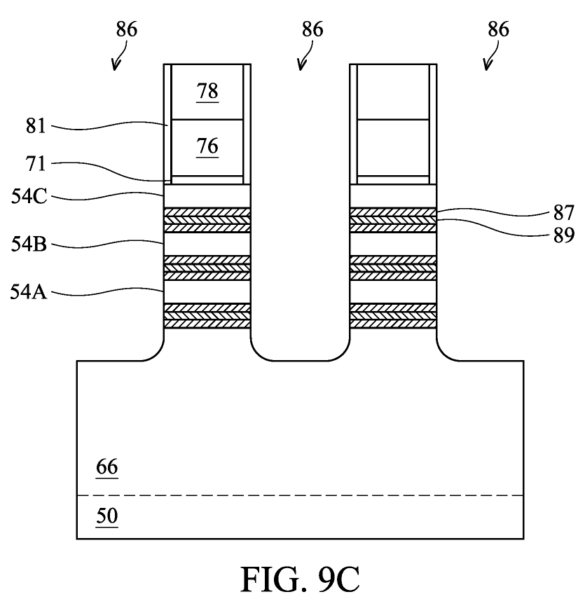

In FIGS. 9A through 9C, the first nanostructures 52 are replaced with first sacrificial layers 87 and second sacrificial layers 89. Replacing the first nanostructures 52 with the first sacrificial layers 87 and the second sacrificial layers 89 may prevent or prevent defects from forming on surfaces of the second nanostructures 54 adjacent the first nanostructures 52 during subsequent annealing processes. Replacing the first nanostructures 52 may include first removing the first nanostructures 52 using a suitable etching process, such as an isotropic etch process, performed through the first recesses 86. The etching process may selectively remove the material of the first nanostructures 52 without significantly removing materials of the second nanostructures 54 or the semiconductor fins 66. In the embodiments in which the first nanostructures 52 comprise silicon germanium and the second nanostructures 54 include silicon, an etching process with tetramethylammonium hydroxide (TMAH), ammonium hydroxide (NH₄OH), or the like are used to remove the first nanostructures 52.

Subsequently, the first sacrificial layers 87 and the second sacrificial layers 89 may be deposited to fill up spaces where the first nanostructures 52 occupied before being removed. The first sacrificial layers 87 may be formed on exposed top and bottom surfaces of the second nanostructures 54 as well as exposed top surfaces of the fins 66 by a suitable deposition process, such as CVD, ALD, or the like, followed by a suitable etching process, such as an anisotropic etching process. The portions of the first sacrificial layers 87 formed on the exposed top surfaces of the second nanostructures 54 and the fins 66 may be referred to as first portions of the first sacrificial layers 87. The portions of the first sacrificial layers 87 formed on the exposed bottom surfaces of the second nanostructures 54 may be referred to as second portions of the first sacrificial layers 87. The first portions of the first sacrificial layers 87 may be separated from the adjacent second portions of the first sacrificial layers 87 by gaps. Then the second sacrificial layers 89 may be formed in the gaps between the first portions of the first sacrificial layers 87 and the adjacent second portions of the first sacrificial layers 87 by a suitable deposition process, such as CVD, ALD, or the like, followed by a suitable etching process, such as an anisotropic etching process.

The first sacrificial layers 87 and the second sacrificial layers 89 may comprise different materials and have different etch rates when exposed to same etchants during subsequent etching processes as described in greater details below. The materials of the first sacrificial layers 87 and the second sacrificial layers 89 may be selected from dielectric materials, such as silicon oxide, aluminum oxide, silicon nitride, or the like. In some embodiments, the first sacrificial layers 87 comprise silicon oxide and the second sacrificial layers 89 comprise aluminum oxide. In some embodiments, the first sacrificial layers 87 comprise aluminum oxide and the second sacrificial layers 89 comprise silicon oxide. In some embodiments, the first sacrificial layers 87 comprise silicon nitride and the second sacrificial layers 89 comprise aluminum oxide. In some embodiments, the first sacrificial layers 87 comprise aluminum oxide and the second sacrificial layers 89 comprise silicon nitride. In some embodiments, the first sacrificial layers 87 comprise silicon nitride and the second sacrificial layers 89 comprise silicon oxide. In some embodiments, the first sacrificial layers 87 comprise silicon oxide and the second sacrificial layers 89 comprise silicon nitride.

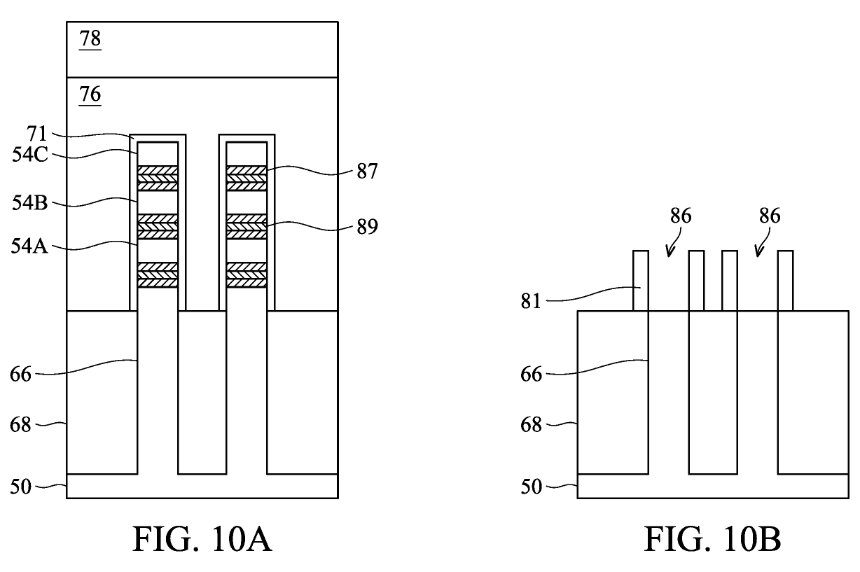

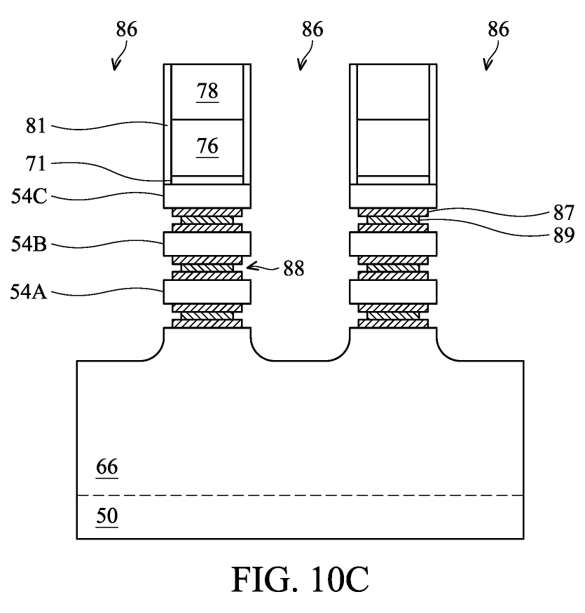

In FIGS. 10A through 10C, the first sacrificial layers 87 and the second sacrificial layers 89 are recessed to form second recesses 88, after which sidewalls of the first sacrificial layers 87 and the second sacrificial layers 89 may be recessed from sidewalls of the second nanostructures 54. In the embodiments illustrated in FIG. 1oC, the sidewalls of the second sacrificial layers 89 are further recessed than the sidewalls of the first portions and second portions of the first sacrificial layers 87. The shapes and sizes of the first sacrificial layers 87 and the second sacrificial layers 89 may partially determine shapes and sizes of subsequently formed inner spacers. The first sacrificial layers 87 and the second sacrificial layers 89 may be recessed by two separate selective etching processes. The first sacrificial layers 87 may be recessed before or after the second sacrificial layers 89. During the selective etching process that selectively recesses the first sacrificial layers 87, the etch rate of the first sacrificial layers 87 is significantly higher than the etch rate of the second sacrificial layers 89. During the selective etching process selectively that recesses the second sacrificial layers 89, the etch rate of the second sacrificial layers 89 is significantly higher than the etch rate of the first sacrificial layers 87. The second nanostructures 54 and the fins 66 may remain substantially intact during the selective etching processes. The sidewalls of the first sacrificial layers 87 and the second sacrificial layers 89 are illustrated as being straight in FIG. 10C as an example, the sidewalls of the first sacrificial layers 87 and the second sacrificial layers 89 may be concave or convex in other embodiments.

In the embodiments where the first sacrificial layers 87 comprise silicon oxide and the second sacrificial layers 89 comprise aluminum oxide, the first sacrificial layers 87 may be selectively recessed using a first etching process, which may be a dry etching process using hydrofluoric acid, a mixture of hydrofluoric acid and ammonia, or the like as etchants, and the second sacrificial layers 89 may be selectively recessed using a second etching process, which may be a wet etching process using a mixture of hydrofluoric acid and a secondary acid, or the like as etchants, at a temperature in a range from about 25 ˚C to about 80 ˚C. The secondary acid may be hydrochloric acid, sulfuric acid, nitric acid, phosphoric acid, acetic acid, or the like. The pH value of the mixture of hydrofluoric acid and the secondary acid may be in a range from about 1 to about 6. In the embodiments where the first sacrificial layers 87 comprise aluminum oxide and the second sacrificial layers 89 comprise silicon oxide, the first sacrificial layers 87 may be selectively recessed using the second etching process and the second sacrificial layers 89 may be selectively recessed using the first etching process.

In the embodiments where the first sacrificial layers 87 comprise silicon nitride and the second sacrificial layers 89 comprise aluminum oxide, the first sacrificial layers 87 may be selectively recessed using the first etching process, and the second sacrificial layers 89 may be selectively recessed using the second etching process, a third etching process, or a fourth etching process. The third etching process may be a wet etching process using a mixture of sulfuric acid and hydrogen peroxide, or the like as etchants. The fourth etching process may be a wet etching process using a mixture of ammonium hydroxide and hydrogen peroxide, or the like as etchants. In the embodiments where the first sacrificial layers 87 comprise aluminum oxide and the second sacrificial layers 89 comprise silicon nitride, the first sacrificial layers 87 may be selectively recessed using the second etching process, the third etching process, or the fourth etching process, and the second sacrificial layers 89 may be selectively recessed using the first etching process.

In the embodiments where the first sacrificial layers 87 comprise silicon nitride and the second sacrificial layers 89 comprise silicon oxide, the first sacrificial layers 87 may be selectively recessed using the second etching process or a fifth etching process which may be a wet etching process using phosphoric acid or the like as etchant, and the second sacrificial layers 89 may be selectively recessed using the first etching process or a sixth etching process, which may be a wet etching process using hydrofluoric acid or the like as etchant. In the embodiments where the first sacrificial layers 87 comprise silicon oxide and the second sacrificial layers 89 comprise silicon nitride, the first sacrificial layers 87 may be selectively recessed using the first etching process or the sixth etching process, and the second sacrificial layers 89 may be selectively recessed using the second etching process or the fifth etching process.

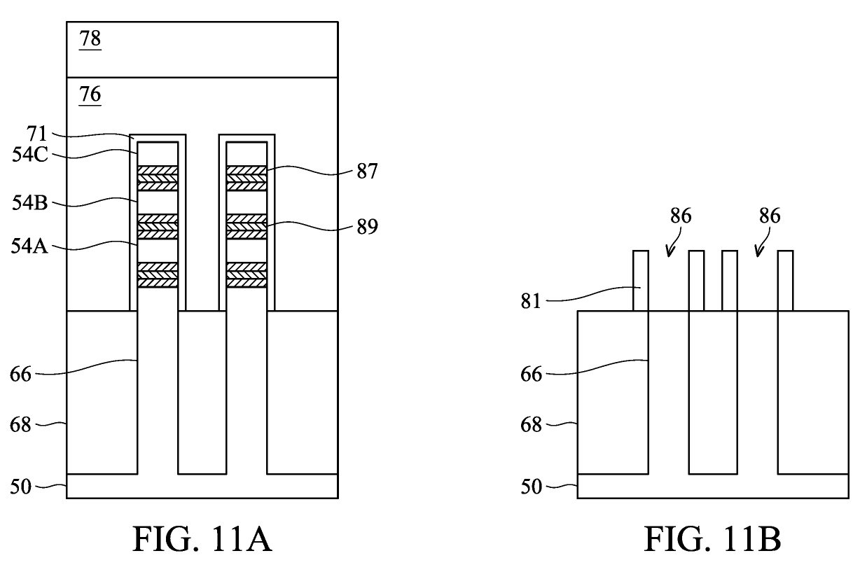

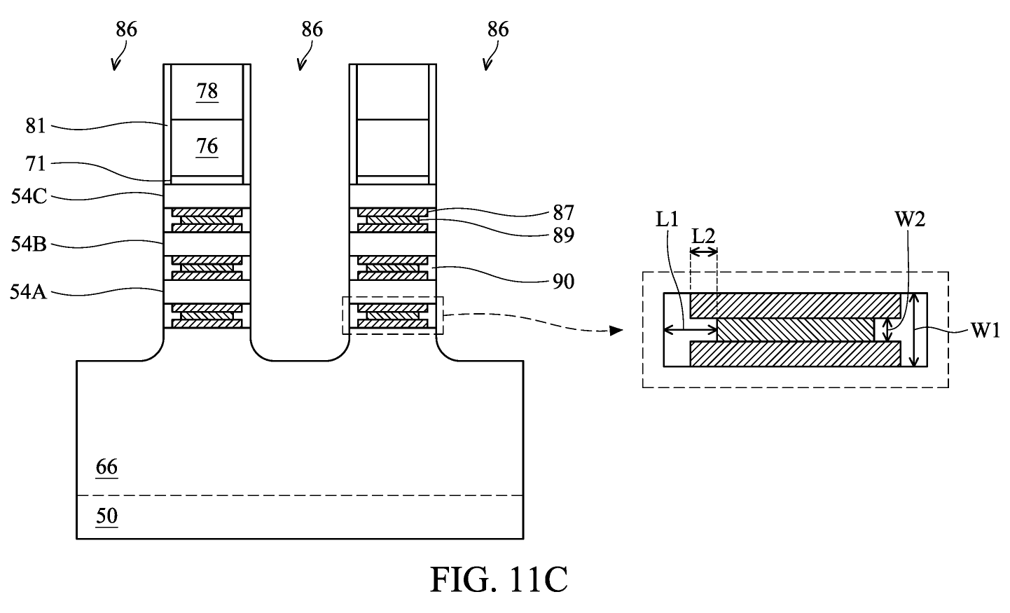

In FIGS. 11A through 11C, inner spacers 90 are formed in the second recesses 88. The inner spacers 90 may provide electrical insulation between the subsequently formed source/drain regions and the subsequently formed gate structures. The inner spacers 90 may extend along sidewalls of the first sacrificial layers 87 and the second sacrificial layers 89. The inner spacers 90 may be in contact with exposed portions of the top surfaces and the bottom surfaces of the second nanostructures 54. The shapes and sizes of the inner spacers 90 may partially depend on shapes and sizes of the first sacrificial layers 87 and the second sacrificial layers 89. In the embodiments illustrated in FIG. 11C, the inner spacers 90 have a “T” shape with protrusion portions in contact with the second sacrificial layers 89. The inner spacers 90 may have corrugated sidewalls in contact with the sidewalls of the first sacrificial layers 87 and the second sacrificial layers 89. The longest portions of the inner spacers 90 may have a length L1. The protrusion portions of the inner spacers 90 may have a length L2 in a range from about 0.5 nm to about 5 nm. A ratio of the length L2 to the length L1 may be in range from about 20% to about 80%. The widest portions of the inner spacers 90 may have a width W1. The protrusion portions of the inner spacers 90 may have a width W2 in a range from about 0.5 nm to about 5 nm. A ratio of the width W2 to the width W1 may be in range from about 20% to about 80%. Such shapes and sizes of the inner spacers 90 may lead to sufficient electrical insulation between the subsequently formed source/drain regions and the subsequently formed gate structures as well as reduced channel resistance as described in greater details below.

The inner spacers 90 may be formed by depositing an inner spacer layer (not separately illustrated) over the structure shown in FIGS. 10A through 10C, and then etching the inner spacer layer. The inner spacer layer may be deposited by a suitable deposition process, such as CVD, ALD, or the like. The inner spacer layer may comprise a material different from and with a high etching selectivity to the materials of the first sacrificial layers 87 and the second sacrificial layers 89. The inner spacer layer may comprise a dielectric material, such as silicon oxycarbonitride or the like. The material of inner spacer layer may have a dielectric constant (k) less than about 3.5. The inner spacer layer may be etched to form the inner spacers 90 by an anisotropic etching process, such as RIE, NBE, or the like. Outer sidewalls of the inner spacers 90 are illustrated in FIG. 11C as being straight and flush with the sidewalls of the second nanostructures 54 as an example, the outer sidewalls of the inner spacers 90 may be concave and recessed from the sidewalls of the second nanostructures 54 or convex and extend beyond the sidewalls of the second nanostructures 54 in some embodiments.

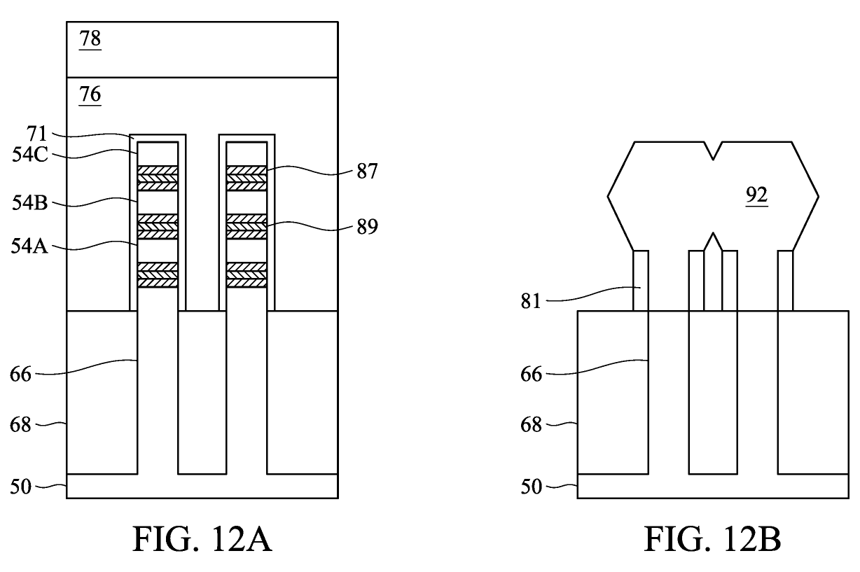

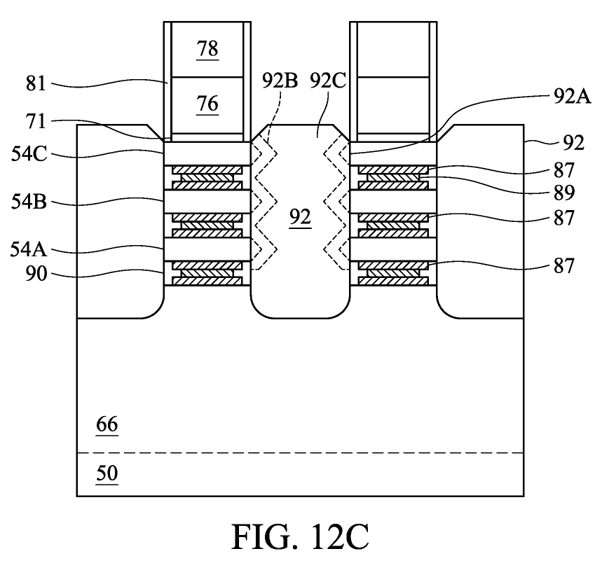

In FIGS. 12A through 12C, epitaxial source/drain regions 92 are formed in the first recesses 86. In some embodiments, the epitaxial source/drain regions 92 may exert stress on the second nanostructures 54, thereby improving performance. As illustrated in FIG. 12C, the epitaxial source/drain regions 92 are formed in the first recesses 86 such that each dummy gate 76 is disposed between respective neighboring pairs of the epitaxial source/drain regions 92.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the second nanostructures 54 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may have surfaces raised from respective surfaces of the second nanostructures 54 and may have facets.

The epitaxial source/drain regions 92, the second nanostructures 54, and/or the substrate 50 may be implanted with dopants to form source/drain regions, similar to the process previously discussed for forming lightly-doped source/drain regions, followed by an annealing process. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 may have facets which expand laterally outward beyond sidewalls of the second nanostructures 54. In some embodiments, these facets cause adjacent epitaxial source/drain regions 92 of a same nano-FET to merge as illustrated by FIG. 12B. In some embodiments, adjacent epitaxial source/drain regions 92 remain separated after the epitaxy process is completed as illustrated by FIG. 12D.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

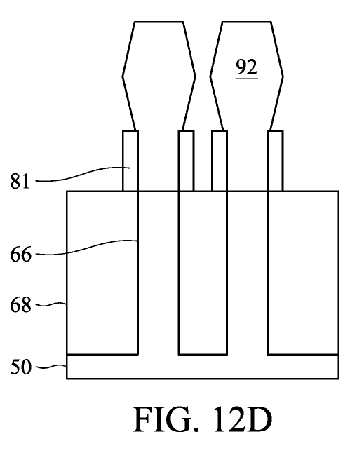

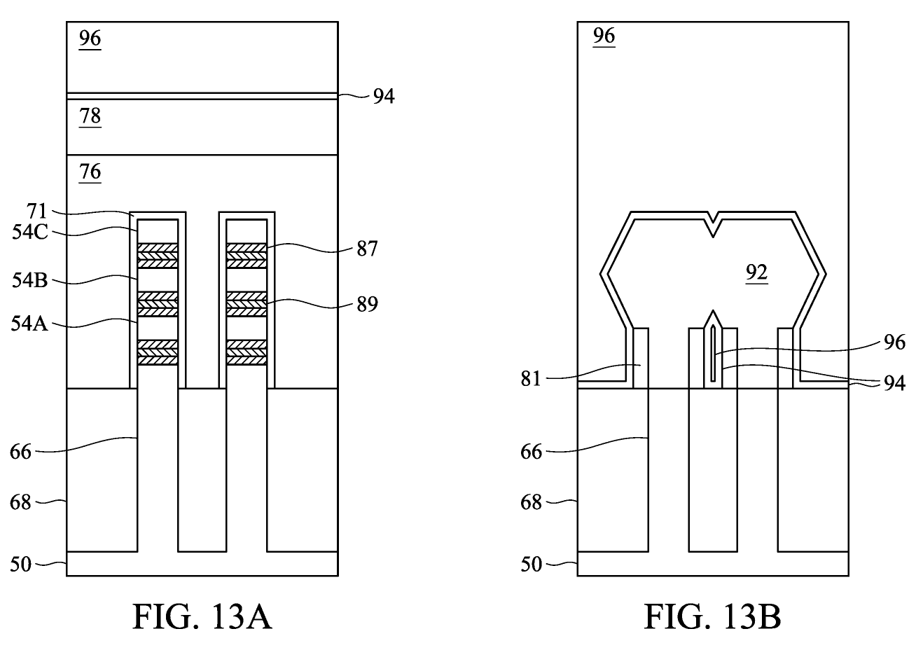

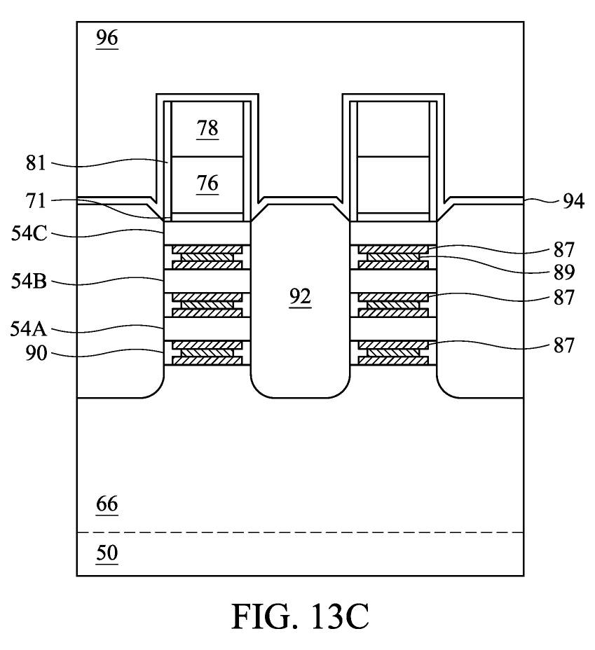

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the spacers 81. The CESL 94 may comprise a dielectric material, such as, silicon nitride, silicon oxide, silicon oxynitride, or the like, having a different etch rate than the material of the overlying first ILD 96.

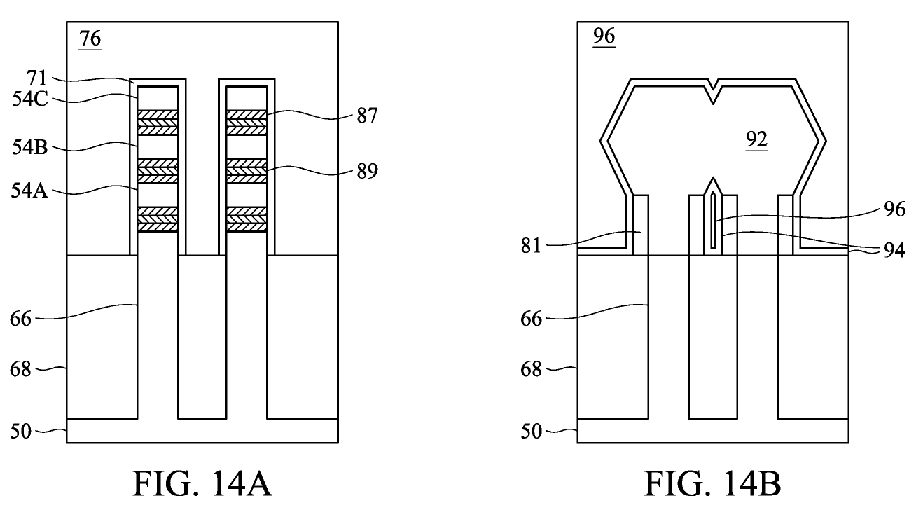

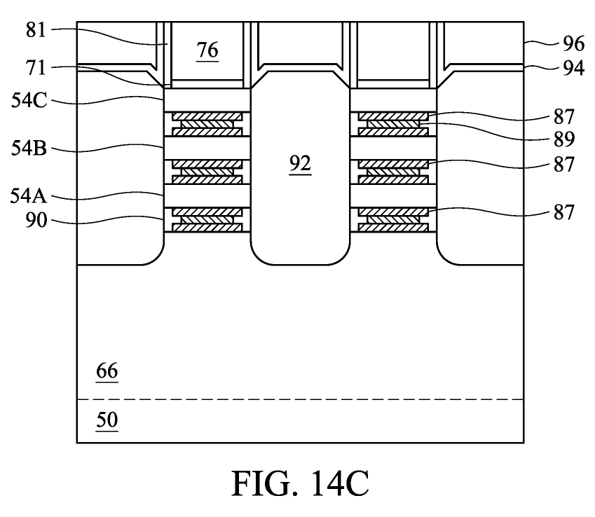

In FIGS. 14A through 14C, a planarization process, such as CMP, may be performed to level the top surface of the first ILD 96 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the spacers 81.

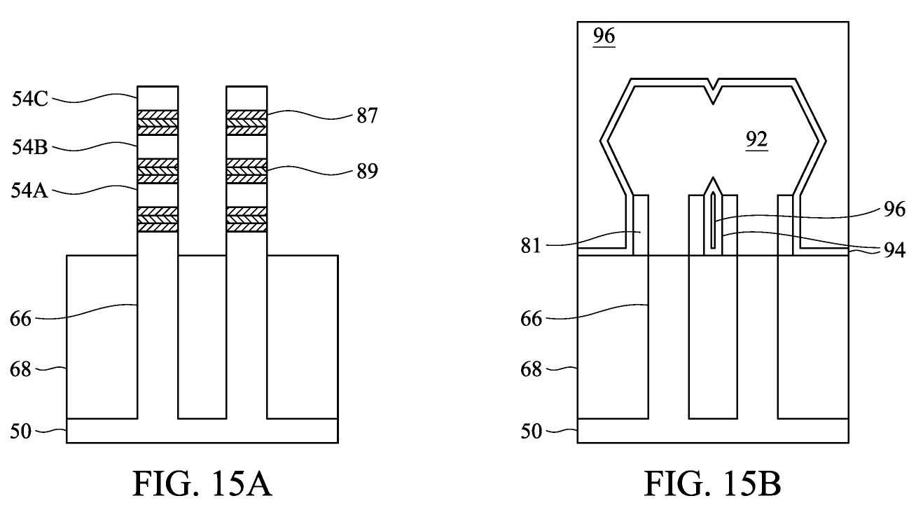

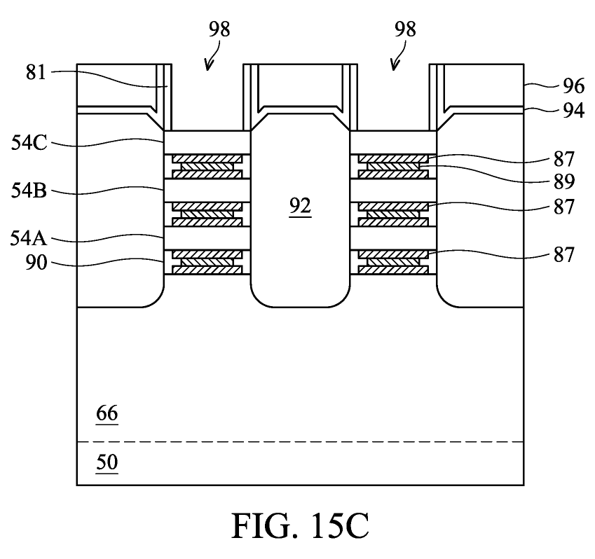

In FIGS. 15A through 15C, the dummy gates 76 and the dummy gate dielectrics 71 are removed in one or more etching processes to form third recesses 98. In some embodiments, the dummy gates 76 and the dummy gate dielectrics 71 are removed by an anisotropic dry etch process. For example, the etching processes may include dry etching processes using etchants that selectively etch the dummy gates 76 and the dummy gate dielectrics 71 at faster rates than the first ILD 96 and/or the spacers 81. Each of the third recess 98 exposes and/or overlies portions of the second nanostructures 54, which act as channel regions in subsequently completed nano-FETs. Portions of the second nanostructures 54, which may act as the channel regions, are disposed between neighboring pairs of the epitaxial source/drain regions 92. During the etching processes, the dummy gate dielectrics 71 may be used as etch stop layers when the dummy gates 76 are removed and may be removed after the removal of the dummy gates 76.

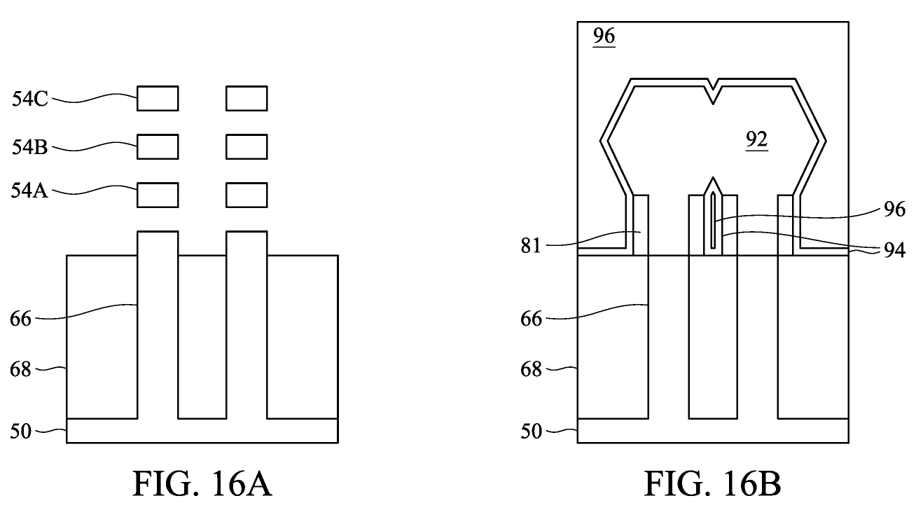

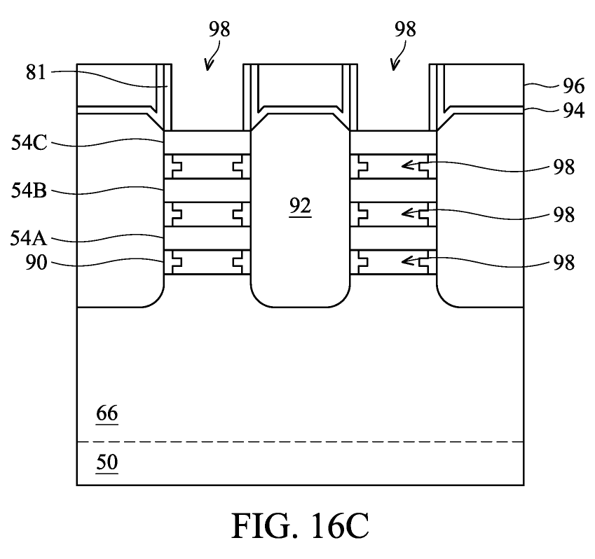

In FIGS. 16A through 16C, the first sacrificial layers 87 and the second sacrificial layers 89 are removed, which extends the third recesses 98. The first sacrificial layers 87 and the second sacrificial layers 89 may be removed by two separate selective etching processes, which may be same or similar to the selective etching processes described above with respect to recessing the first sacrificial layers 87 and the second sacrificial layers 89 in FIGS. 10A through 10C. The second nanostructures 54, the fins 66, and the inner spacers 90 may remain substantially intact during the selective etching processes. In the embodiments illustrated in FIGS. 16A through 16C, the first sacrificial layers 87 and the second sacrificial layers 89 are completely removed. In other embodiments, the first sacrificial layers 87 and the second sacrificial layers 89 are partially removed.

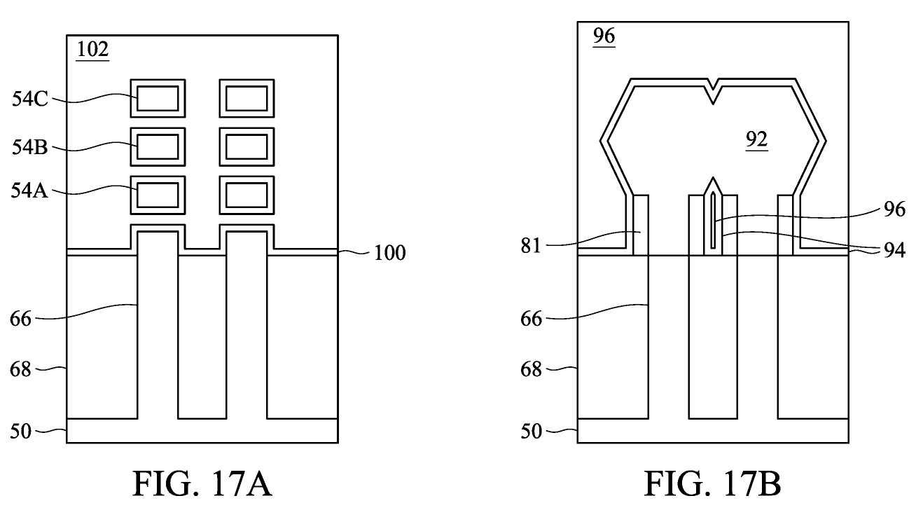

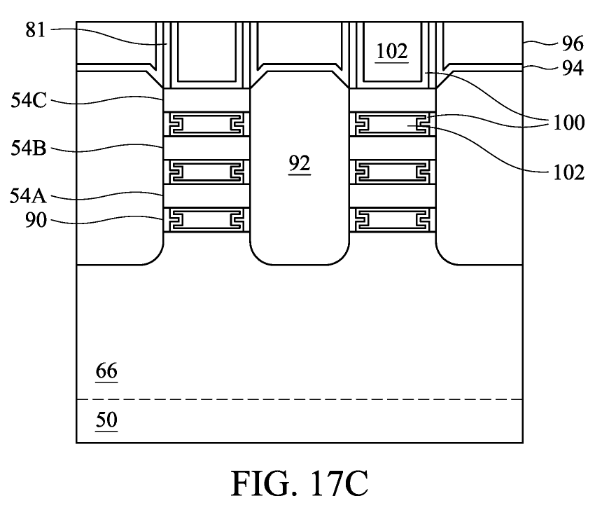

In FIGS. 17A through 17C, gate dielectric layers 100 and gate electrodes 102 are formed in the third recesses 98. The gate dielectric layers 100 and the gate electrodes 102 may fill up spaces where the first sacrificial layers 87 and the second sacrificial layers 89 occupied before being removed. The gate dielectric layers 100 may be deposited conformally in the third recesses 98 on the top surfaces, sidewalls, and bottom surfaces of the second nanostructures 54, and on the sidewalls of the inner spacers 90. The gate dielectric layers 100 may also be deposited on the first ILD 96, the CESL 94, the spacers 81, and the STI regions 68. The gate dielectric layers 100 may comprise one or more dielectric layers, such as silicon oxide, a metal oxide, the like, or combinations thereof. The gate dielectric layers 100 may be formed by a suitable deposition process, such as ALD, CVD, or the like. The gate electrodes 102 may be deposited over the gate dielectric layers 100, respectively, and fill the remaining portions of the third recesses 98. The gate electrodes 102 may comprise a conductive material, such as titanium nitride, titanium oxide, tantalum nitride, tantalum carbide, cobalt, ruthenium, aluminum, tungsten, the like, or combinations thereof. The gate electrodes 102 are illustrated in FIGS. 17A and 17C as single layers as an example, the gate electrodes 102 may comprise any number of liner layers, any number of work function tuning layers, and a fill material.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the gate electrodes 102 over the top surface of the first ILD 96. The remaining portions of the gate electrodes 102 and the gate dielectric layers 100 may be collectively referred to as gate structures. The shapes and sizes of the gate structures may partially depend on shapes and sizes of the inner spacers 90. In the embodiments illustrated in FIG. 17C, the inner spacers 90 have the “T” shape with corrugated sidewalls in contact with corresponding corrugated sidewalls of the gate structures. The protrusion portions of the inner spacers 90 may protrude from the epitaxial source/drain regions 92 towards the gate structures. Such shapes and sizes of the inner spacers 90 may separate epitaxial source/drain regions 92 from the gate structures and provide sufficient electrical insulation between the epitaxial source/drain regions 92 and the gate structures, thereby reducing or eliminating current leakage between the gate structures and the epitaxial source/drain regions 92. Such shapes and sizes of the gate structures, which may be partially determined by the shapes and sizes of the inner spacers 90 may lead to reduced resistance in the channel regions (e.g., the second nanostructures 54). As a result, the performance and reliability of the subsequently formed semiconductor device may be improved.

Using the gate structure between the second nanostructure 54A and the second nanostructure 54B as an example, the gate structure may comprise a first protrusion portion and a second protrusion portion protruding towards the inner spacer 90 on each side of the gate structure. A recess may be between the first protrusion portion and the second protrusion portion of the gate structure on each side of the gate structure and the protrusion portion of the corresponding inner spacer 90 may protrude into the recess. As a result, on each side of the gate structure, the protrusion portion of the inner spacer 90 may be between the first protrusion portion and the second protrusion portion of the gate structure, and the protrusion portion of the inner spacer 90 may be in contact with a bottom surface of the first protrusion portion of the gate structure and a top surface of the second protrusion portion of the gate structure. On each side of the gate structure, the protrusion portion of the inner spacer 90 may be between the second nanostructure 54A and the first protrusion portion of the gate structure, the protrusion portion of the inner spacer 90 may be between the second nanostructure 54B and the second protrusion portion of the gate structure, the first protrusion portion of the gate structure may be between the second nanostructure 54B and the protrusion portion of the inner spacer 90, and the second protrusion portion of the gate structure may be between the second nanostructure 54A and the protrusion portion of the inner spacer 90.

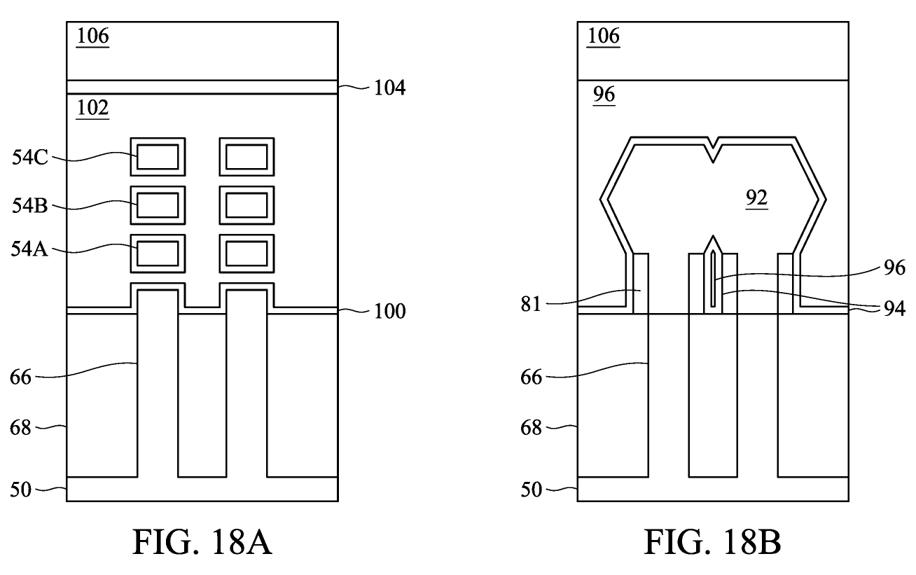

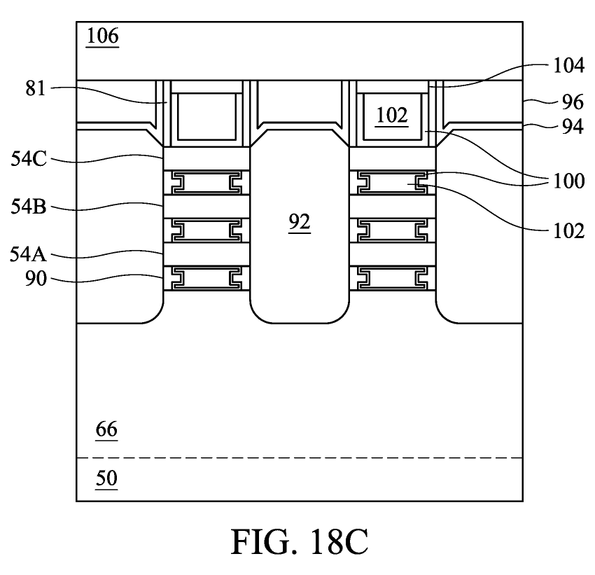

In FIGS. 18A through 18C, the gate structures (including the gate dielectric layers 100 and the corresponding overlying gate electrodes 102) are recessed, gate masks 104 are formed in the recesses, and a second ILD 106 is formed over the first ILD 96 and the gate masks 104. The recesses may be formed directly over the gate structures and between opposing portions of spacers 81. Gate masks 104 may comprise one or more layers of dielectric material, such as silicon nitride, silicon oxynitride, or the like. A planarization process may be performed to remove excess material of the gate masks 104. The second ILD 106 may be formed of a dielectric material, such as PSG, BSG, BPSG, USG, or the like, and may be deposited by any suitable method, such as CVD, PECVD, FCVD, or the like.

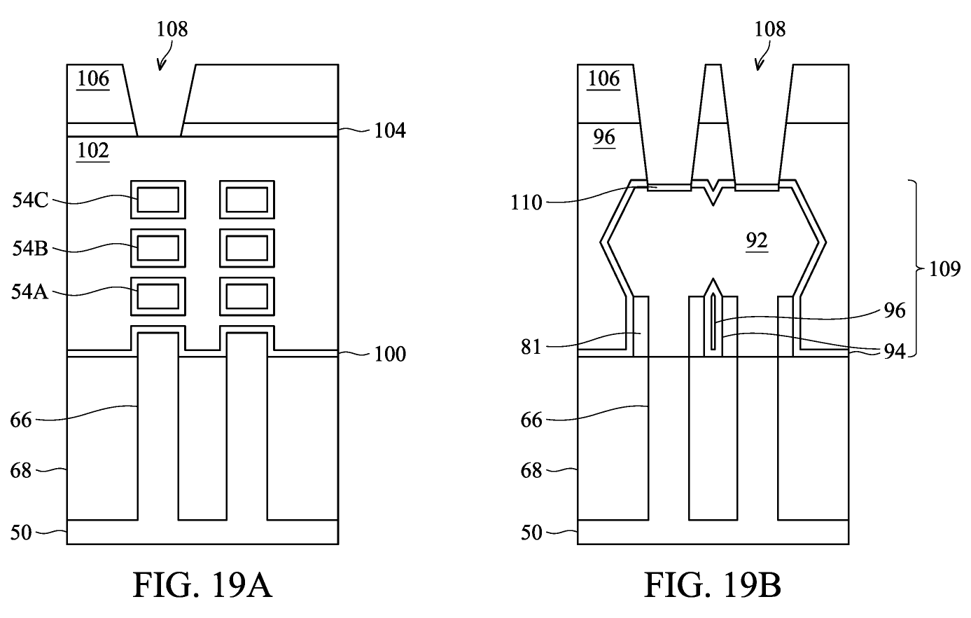

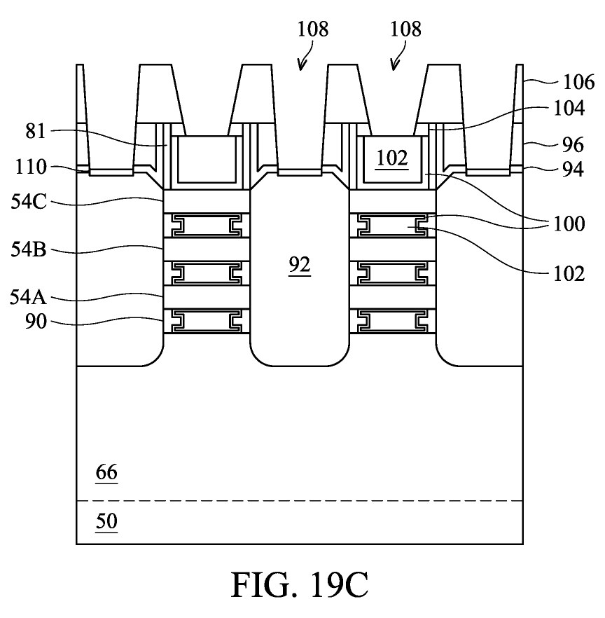

In FIGS. 19A through 19C, the second ILD 106, the first ILD 96, the CESL 94, and the gate masks 104 are etched to form fourth recesses 108 exposing surfaces of the epitaxial source/drain regions 92 and/or some of the gate structures. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal annealing process to form the first silicide regions 110. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

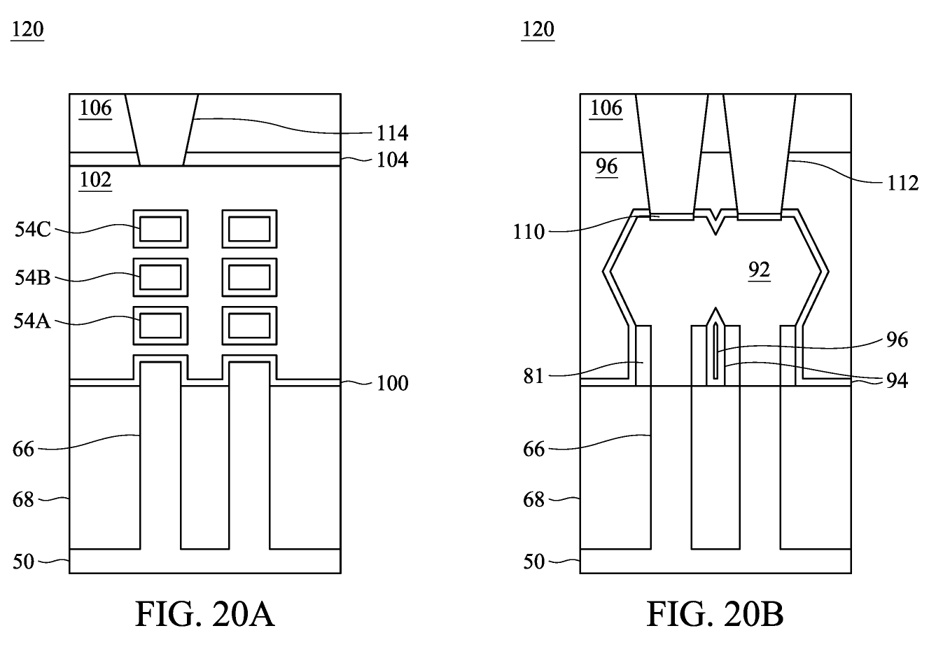

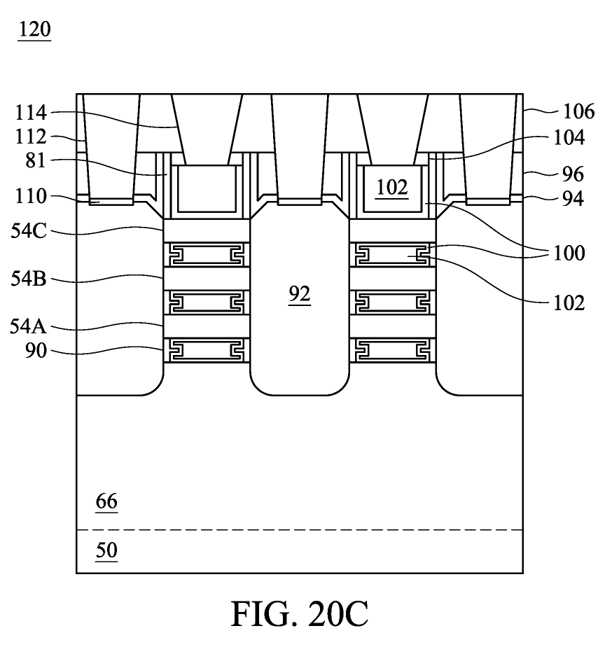

In FIGS. 20A through 20C, source/drain contacts 112 and gate contacts 114, which may be also referred to as conductive contacts, are formed in the fourth recesses 108. The structure shown in FIGS. 20A through 20C may be referred to as semiconductor device 120. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106.

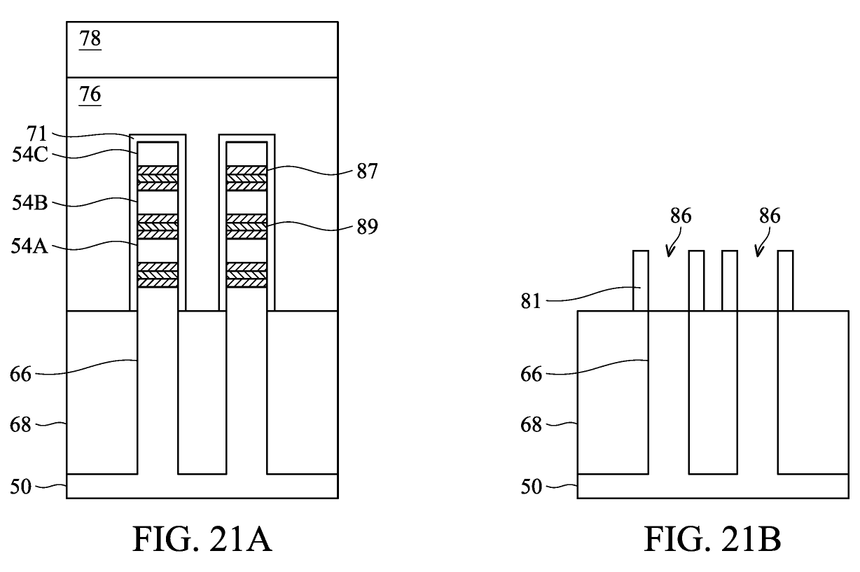

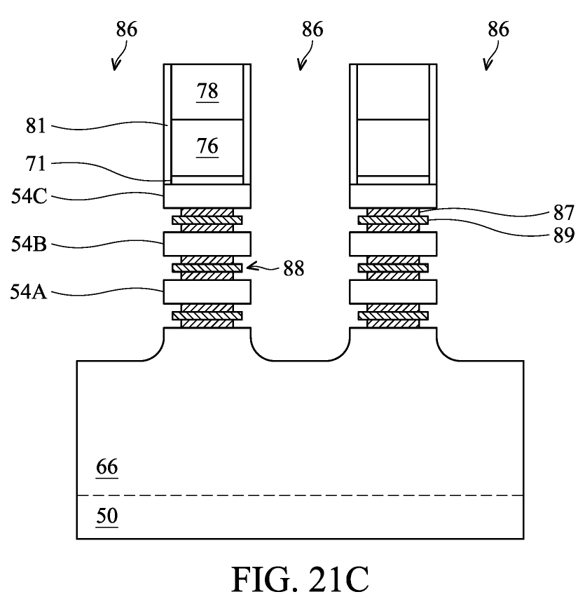

FIGS. 21A through 24C are views of intermediate processes in the manufacturing of a semiconductor device (e.g., a nano-FET), in accordance with some embodiments. FIGS. 21A, 22A, 23A, and FIG. 24A illustrate cross-sectional views along the reference cross-section A-A’ illustrated in FIG. 1. FIGS. 21B, 22B, 23B, and FIG. 24B illustrate cross-sectional views along the reference cross-section B-B’ illustrated in FIG. 1. FIGS. 21C, 22C, 23C, and FIG. 24C illustrate cross-sectional views along the reference cross-section C-C’ illustrated in FIG. 1.

FIGS. 21A through 21C illustrate structures similar to the ones shown in FIGS. 10A through 10C, which may be based on structures formed by the processes similar to the ones shown in FIGS. 1 through 9C, wherein like numerals refer to like features formed by like processes. In FIGS. 21A through 21C, the first sacrificial layers 87 and the second sacrificial layers 89 are recessed to form second recesses 88, after which sidewalls of the first sacrificial layers 87 and the second sacrificial layers 89 may be recessed from sidewalls of the second nanostructures 54. In the embodiments illustrated in FIG. 21C, the sidewalls of the first portions and second portions of the first sacrificial layers 87 are further recessed than the sidewalls of the second sacrificial layers 89. The first sacrificial layers 87 and the second sacrificial layers 89 may be recessed by two separate selective etching processes, which may be same or similar to the selective etching processes described above with respect to recessing the first sacrificial layers 87 and the second sacrificial layers 89 in FIGS. 10A through 10C. The first sacrificial layers 87 may be recessed before or after the second sacrificial layers 89. The second nanostructures 54 and the fins 66 may remain substantially intact during the selective etching processes. The sidewalls of the first sacrificial layers 87 and the second sacrificial layers 89 are illustrated as being straight in FIG. 21C as an example, the sidewalls of the first sacrificial layers 87 and the second sacrificial layers 89 may be concave or convex in other embodiments.

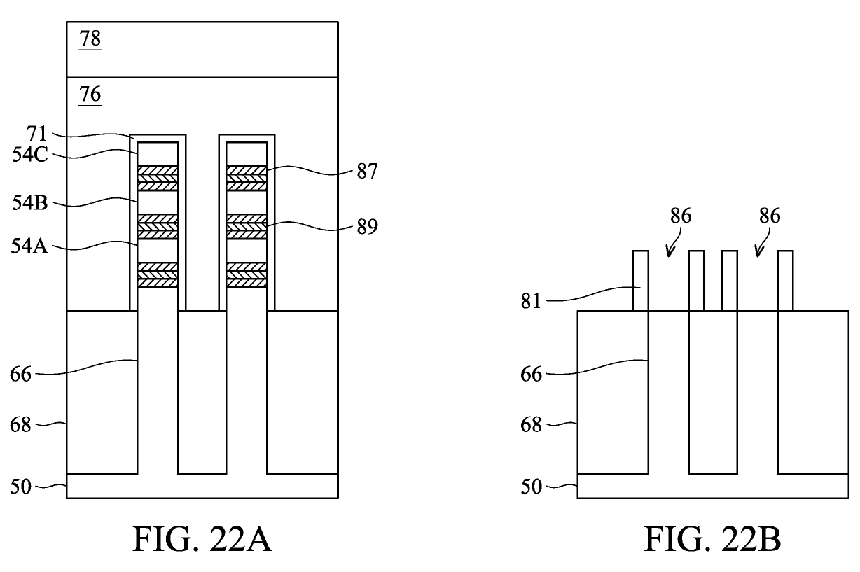

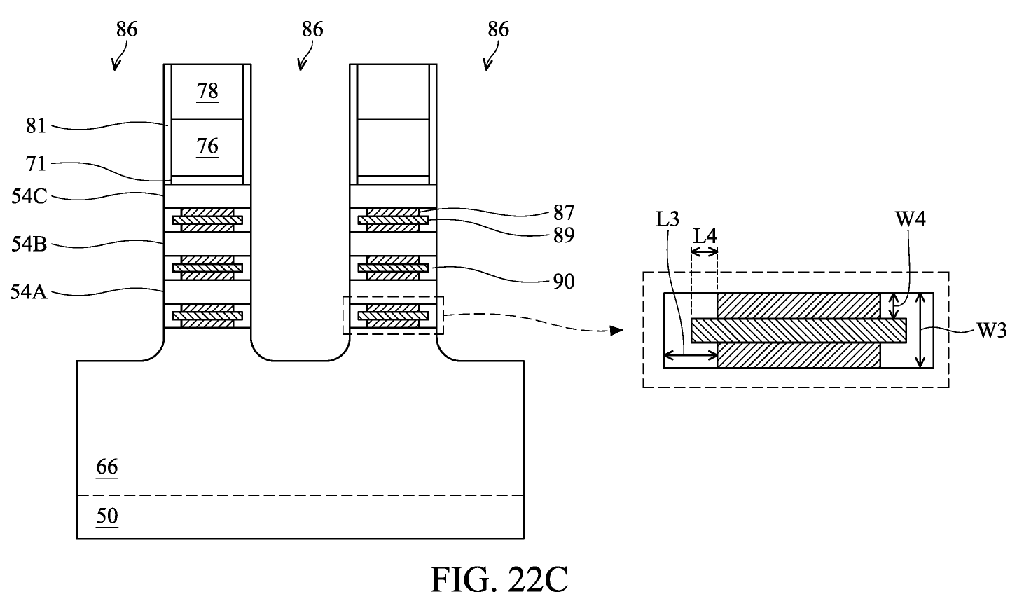

In FIGS. 22A through 22C, inner spacers 90 are formed in the second recesses 88. The inner spacers 90 may provide electrical insulation between the subsequently formed source/drain regions and the subsequently formed gate structures. The inner spacers 90 may extend along sidewalls of the first sacrificial layers 87 and the second sacrificial layers 89. The inner spacers 90 may be in contact with exposed portions of the top surfaces and the bottom surfaces of the second nanostructures 54. The shapes and sizes of the inner spacers 90 may partially depend on shapes and sizes of the first sacrificial layers 87 and the second sacrificial layers 89. In the embodiments illustrated in FIG. 22C, the inner spacers 90 have a “U” shape with protrusion portions in contact with the first portions and second portions of the first sacrificial layers 87. The inner spacers 90 may have corrugated sidewalls in contact with the sidewalls of the first sacrificial layers 87 and the second sacrificial layers 89. The longest portions of the inner spacers 90 may have a length L3. The protrusion portions of the inner spacers 90 may have a length L4 in a range from about 0.5 nm to about 5 nm. A ratio of the length L4 to the length L3 may be in range from about 20% to about 80%. The widest portions of the inner spacers 90 may have a width W3. The protrusion portions of the inner spacers 90 may have a width W4 in a range from about 0.5 nm to about 5 nm. A ratio of the width W4 to the width W3 may be in range from about 20% to about 80%. Such shapes and sizes of the inner spacers 90 may lead to sufficient electrical insulation between the subsequently formed source/drain regions and the subsequently formed gate structures as well as reduced channel resistance as described in greater details below.

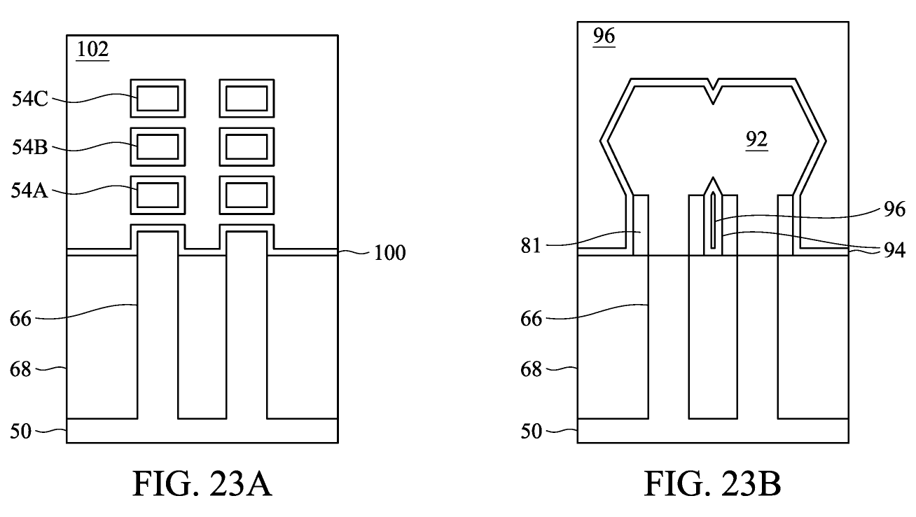

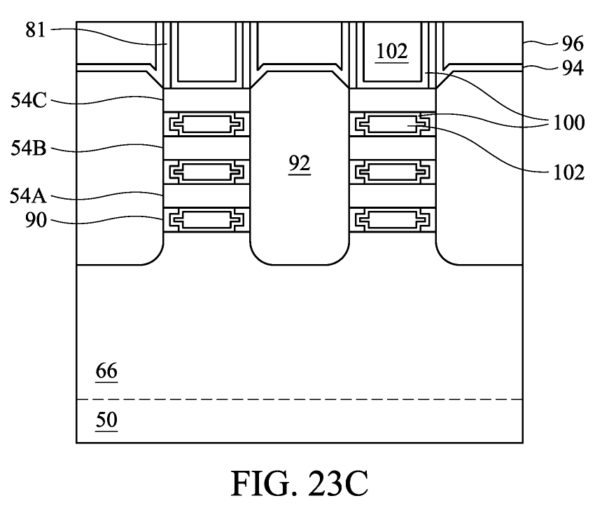

FIGS. 23A through 23C illustrate structures similar to the ones shown in FIGS. 17A through 17C, which may be based on structures formed by the processes similar to the ones shown in FIGS. 12A through 16C, wherein like numerals refer to like features formed by like processes. In FIGS. 23A through 23C, the gate dielectric layers 100 and the gate electrodes 102 are formed in the third recesses 98. The gate dielectric layers 100 and the gate electrodes 102 may fill up spaces where the first sacrificial layers 87 and the second sacrificial layers 89 occupied before being removed. The gate dielectric layers 100 and the gate electrodes 102 may be formed by same or similar methods described above with respect FIGS. 17A through 17C. The gate electrodes 102 and the gate dielectric layers 100 may be collectively referred to as gate structures.

The shapes and sizes of the gate structures may partially depend on shapes and sizes of the inner spacers 90. In the embodiments illustrated in FIG. 23C, the inner spacers 90 have the “U” shape with corrugated sidewalls in contact with corresponding corrugated sidewalls of the gate structures. The protrusion portions of the inner spacers 90 may protrude from the epitaxial source/drain regions 92 towards the gate structures. Such shapes and sizes of the inner spacers 90 may separate epitaxial source/drain regions 92 from the gate structures and provide sufficient electrical insulation between the epitaxial source/drain regions 92 and the gate structures, thereby reducing or eliminating current leakage between the gate structures and the epitaxial source/drain regions 92. Such shapes and sizes of the gate structures, which may be partially determined by the shapes and sizes of the inner spacers 90 may lead to reduced resistance in the channel regions (e.g., the second nanostructures 54). As a result, the performance and reliability of the subsequently formed semiconductor device may be improved.

Using the gate structure between the second nanostructure 54A and the second nanostructure 54B as an example, the gate structure may comprise a protrusion portion protruding towards the inner spacer 90 on each side of the gate structure. A recess may be between a first protrusion portion and a second protrusion portion of the inner spacer 90 on each side of the gate structure and the corresponding protrusion portion of the gate structure may protrude into the recess. As a result, on each side of the gate structure, the protrusion portion of the gate structure may be between the first protrusion portion and the second protrusion portion of the inner spacer 90, and the protrusion portion of the gate structure may be in contact with a bottom surface of the first protrusion portion of the inner spacer 90 and a top surface of the second protrusion portion of the inner spacer 90. On each side of the gate structure, the second protrusion portion of the inner spacer 90 may be between the second nanostructure 54A and the protrusion portion of the gate structure, the first protrusion portion of the inner spacer 90 may be between the second nanostructure 54B and the protrusion portion of the gate structure, the protrusion portion of the gate structure may be between the second nanostructure 54B and the second protrusion portion of the inner spacer 90, and the protrusion portion of the gate structure may be between the second nanostructure 54A and the first protrusion portion of the inner spacer 90.

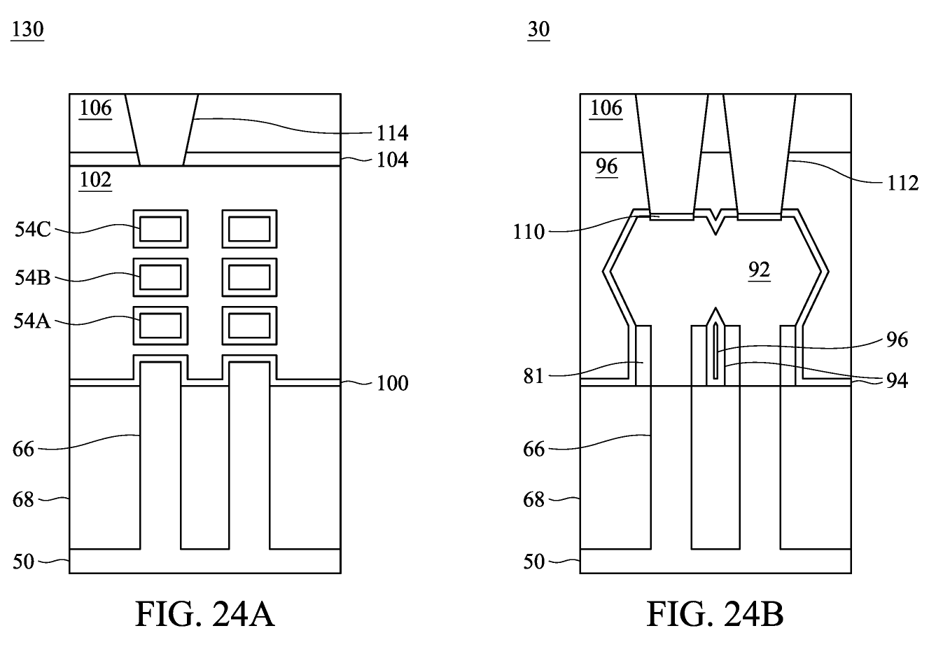

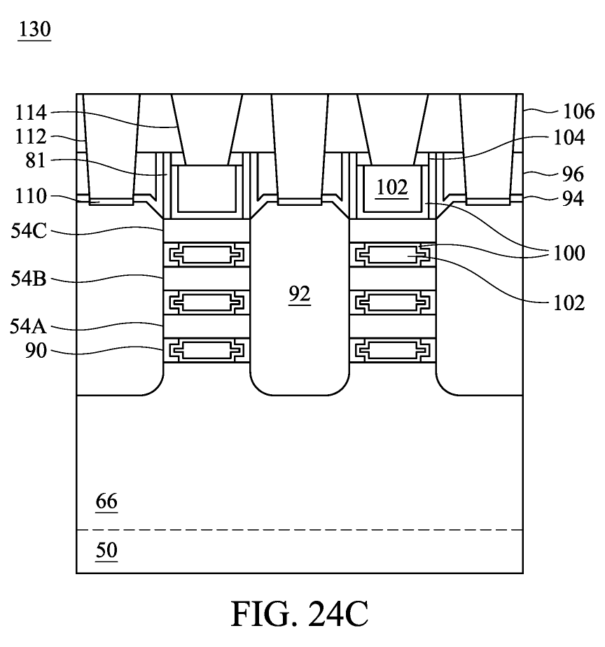

FIGS. 24A through 24C illustrate structures similar to the ones shown in FIGS. 20A through 20C, which may be based on structures formed by the processes similar to the ones shown in FIGS. 18A through 19C, wherein like numerals refer to like features formed by like processes. The structure shown in FIGS. 24A through 24C may be referred to as semiconductor device 130. In FIGS. 24A through 24C, source/drain contacts 112 and gate contacts 114, which may be also referred to as conductive contacts, are formed in the fourth recesses 108. The source/drain contacts 112 and gate contacts 114 may be formed by same or similar methods described above with respect FIGS. 20A through 20C.

The embodiments of the present disclosure have some advantageous features. By forming and recessing the first sacrificial layers 87 and the second sacrificial layers 89, the inner spacers 90 and the gate structures may be formed to have certain shapes and sizes. The inner spacers 90 with such shapes and sizes may provide sufficient electrical insulation between the epitaxial source/drain regions 92 and the gate structures, thereby reducing or eliminating the current leakage between the gate structures and the epitaxial source/drain regions 92. The gate structures with such shapes and sizes may lead to reduced resistance in the channel regions (e.g., the second nanostructures 54). As a result, the performance and reliability of the semiconductor devices may be improved.

In an embodiment, a semiconductor device includes a first nanostructure and a second nanostructure; a gate structure between the first nanostructure and the second nanostructure; a source/drain region along sidewalls of the first nanostructure and the second nanostructure; and a spacer layer between the source/drain region and gate structure, wherein a first portion of the spacer layer protrudes from the source/drain region towards the gate structure, and wherein the first portion of the spacer layer protrudes into a recess of the gate structure. In an embodiment, the first portion of the spacer layer is between a first portion of the gate structure and a second portion of the gate structure. In an embodiment, the first portion of the spacer layer is in contact with a top surface of the first portion of the gate structure and a bottom surface of the second portion of the gate structure. In an embodiment, the first portion of the gate structure is between the first portion of the spacer layer and the first nanostructure, and wherein the second portion of the gate structure is between the first portion of the spacer layer and the second nanostructure. In an embodiment, a second portion of the spacer layer is in contact with the first nanostructure and the second nanostructure. In an embodiment, the spacer layer has a “T” shape. In an embodiment, the spacer layer has a corrugated sidewall in contact with the gate structure.

In an embodiment, method of forming a semiconductor device includes forming a first nanostructure and a second nanostructure over a fin; forming a first sacrificial layer, wherein a first portion of the first sacrificial layer is on the first nanostructure and a second portion of the first sacrificial layer is on the second nanostructure; forming a second sacrificial layer between the first portion of the first sacrificial layer and the second portion of the first sacrificial layer; forming a spacer layer on the first portion of the first sacrificial layer, the second portion of the first sacrificial layer, and the second sacrificial layer, wherein the spacer layer has a “T” shape or a “U” shape; forming a source/drain region on the first nanostructure, the second nanostructure, and the spacer layer; forming a first opening by removing the first sacrificial layer and the second sacrificial layer; and forming a gate structure in the first opening. In an embodiment, a first portion of the spacer layer protrudes into a recess of the gate structure, and wherein a first portion of the spacer layer is in contact with a bottom surface of a first portion of the gate structure and a top surface of a second portion of the gate structure. In an embodiment, a first portion of the gate structure protrudes into a recess of the spacer layer, and wherein a first portion of the gate structure is in contact with a bottom surface of a first portion of the spacer layer and a top surface of a second portion of the spacer layer. In an embodiment, the gate structure has a corrugated sidewall in contact with the spacer layer. In an embodiment, the first sacrificial layer comprises aluminum oxide and the second sacrificial layer comprises silicon oxide. In an embodiment, the first sacrificial layer comprises silicon oxide and the second sacrificial layer comprises aluminum oxide.

In an embodiment, a method of forming a semiconductor device includes forming a first nanostructure and a second nanostructure over a fin; forming a first sacrificial layer, wherein a first portion of the first sacrificial layer is on a top surface of the first nanostructure and a second portion of the first sacrificial layer is on a bottom surface of the second nanostructure; forming a second sacrificial layer between the first portion of the first sacrificial layer and the second portion of the first sacrificial layer; recessing the first sacrificial layer and the second sacrificial layer; forming a spacer layer on a sidewall of the first portion of the first sacrificial layer, a sidewall of the second portion of the first sacrificial layer, and a sidewall of the second sacrificial layer; and forming a source/drain region on sidewalls of the first nanostructure, the second nanostructure, and the spacer layer. In an embodiment, the first sacrificial layer comprises a first dielectric material and the second sacrificial layer comprises a second dielectric material different from the first dielectric material. In an embodiment, recessing the first sacrificial layer and the second sacrificial layer comprises: recessing the first sacrificial layer by a first etching process, wherein the first sacrificial layer is removed at a higher rate than the second sacrificial layer; and recessing the second sacrificial layer by a second etching process, wherein the second sacrificial layer is removed at a higher rate than the first sacrificial layer. In an embodiment, the sidewall of the second sacrificial layer is further recessed than the sidewall of the first portion of the first sacrificial layer and the sidewall of the second portion of the first sacrificial layer after recessing the first sacrificial layer and the second sacrificial layer. In an embodiment, the sidewall of the first portion of the first sacrificial layer and the sidewall of the second portion of the first sacrificial layer is further recessed than the sidewall of the second sacrificial layer after recessing the first sacrificial layer and the second sacrificial layer. In an embodiment, wherein the spacer layer has a “T” shape or a “U” shape. In an embodiment, the method further includes forming a first opening by removing the first sacrificial layer and the second sacrificial layer; and forming a gate structure in the first opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first nanostructure and a second nanostructure;
a gate structure between the first nanostructure and the second nanostructure;
a source/drain region along sidewalls of the first nanostructure and the second nanostructure; and
a spacer layer between the source/drain region and the gate structure, wherein a first portion of the gate structure protrudes into a recess of the spacer layer, and wherein the first portion of the gate structure is in contact with a bottom surface of a first portion of the spacer layer and a top surface of a second portion of the spacer layer.

2. The semiconductor device of claim 1, wherein the first portion of the spacer layer is between the first nanostructure and the first portion of the gate structure, and wherein the second portion of the spacer layer is between the second nanostructure and the first portion of the gate structure.

3. The semiconductor device of claim 1, wherein the spacer layer has a U shape.

4. The semiconductor device of claim 1, wherein the spacer layer has a corrugated sidewall in contact with the gate structure.

5. The semiconductor device of claim 1, wherein a third portion of the spacer layer is in contact with the first nanostructure and the second nanostructure.

6. The semiconductor device of claim 1, wherein the spacer layer comprises silicon oxycarbonitride.

7. A method comprising:forming a first nanostructure and a second nanostructure over a fin;
forming a first sacrificial layer, wherein a first portion of the first sacrificial layer is on the first nanostructure and a second portion of the first sacrificial layer is on the second nanostructure;
forming a second sacrificial layer between the first portion of the first sacrificial layer and the second portion of the first sacrificial layer, the second sacrificial layer comprising a material different from a material of the first sacrificial layer;
recessing the first sacrificial layer and the second sacrificial layer, wherein after the recessing, sidewalls of the first sacrificial layer and the second sacrificial layer form a corrugated profile;
forming an inner spacer on the sidewalls of the first sacrificial layer and the second sacrificial layer, the inner spacer having a corrugated sidewall;
forming a source/drain region on sidewalls of the first nanostructure and the second nanostructure and on the inner spacer;
removing the first sacrificial layer and the second sacrificial layer to form an opening; and
forming a gate structure in the opening, the gate structure having a corrugated sidewall in contact with the corrugated sidewall of the inner spacer.

8. The method of claim 7, wherein the first sacrificial layer comprises a first dielectric material and the second sacrificial layer comprises a second dielectric material different from the first dielectric material.

9. The method of claim 8, wherein the first dielectric material comprises silicon oxide and the second dielectric material comprises aluminum oxide.

10. The method of claim 8, wherein the first dielectric material comprises aluminum oxide and the second dielectric material comprises silicon oxide.

11. The method of claim 7, wherein the inner spacer has a T shape or a U shape.

12. The method of claim 7, wherein a first portion of the inner spacer protrudes into a recess of the gate structure.

13. The method of claim 7, wherein a first portion of the gate structure protrudes into a recess of the inner spacer.

14. A method comprising:
forming a first nanostructure and a second nanostructure over a fin;
forming a first sacrificial layer, wherein a first portion of the first sacrificial layer is on a top surface of the first nanostructure and a second portion of the first sacrificial layer is on a bottom surface of the second nanostructure;
forming a second sacrificial layer between the first portion of the first sacrificial layer and the second portion of the first sacrificial layer, the first sacrificial layer comprising a first dielectric material and the second sacrificial layer comprising a second dielectric material different from the first dielectric material;
recessing the first sacrificial layer by a first etching process, wherein the first sacrificial layer is removed at a higher rate than the second sacrificial layer;
recessing the second sacrificial layer by a second etching process, wherein the second sacrificial layer is removed at a higher rate than the first sacrificial layer, and wherein after the recessing a sidewall of the second sacrificial layer is further recessed than a sidewall of the first portion of the first sacrificial layer and a sidewall of the second portion of the first sacrificial layer;
forming an inner spacer on the sidewall of the first portion of the first sacrificial layer, the sidewall of the second portion of the first sacrificial layer, and the sidewall of the second sacrificial layer;
forming a source/drain region on sidewalls of the first nanostructure and the second nanostructure;
removing the first sacrificial layer and the second sacrificial layer to form an opening; and
forming a gate structure in the opening, wherein a first portion of the inner spacer protrudes into a recess of the gate structure.

15. The method of claim 14, wherein the inner spacer has a T shape.

16. The method of claim 14, wherein the first portion of the inner spacer is in contact with a bottom surface of a first portion of the gate structure and a top surface of a second portion of the gate structure.

17. The method of claim 14, wherein the first dielectric material comprises silicon oxide and the second dielectric material comprises aluminum oxide.

18. The method of claim 14, wherein the first dielectric material comprises silicon nitride and the second dielectric material comprises aluminum oxide.

19. The method of claim 14, wherein the first etching process comprises a dry etching process using hydrofluoric acid or a mixture of hydrofluoric acid and ammonia.

20. The method of claim 14, wherein the second etching process comprises a wet etching process using a mixture of hydrofluoric acid and a secondary acid.
